(19) United States
(12) Patent Application Publication
(10) Pub. No.: US 2006/0163059 A1
(43) Pub. Date: Jul. 27, 2006

(54) Sputtering cathode, production method and corresponding cathode

(76) Inventors: Klaus Leitner, Feld-kirch-Nofels (AT); Andreas M. R. Hiermer, Trubbach (CH)

Correspondence Address: NOTARO AND MICHALOS, 100 DUTCH HILL ROAD, SUITE 110, ORANGEBURG, NY, 10962-2100, US

(21) Appl. No.: 10/525,993

(22) PCT Filed: Aug. 27, 2003
(86) PCT No.: PCT/CH03/00580

§ 371 Date: Feb. 28, 2005

(30) Foreign Application Priority Data
Sep. 3, 2002 (CH) 150/02

(51) Int. Cl. C23C 14/00

(52) U.S. Cl. 204/298.09; 204/298.16; 204/298.12

(57) ABSTRACT

Sputtering cathode and method has a basic cathode body with cooling arrangement, and a cooling contact body disposed between the cooling arrangement and a target such that it is heat conducting, and wherein the contact face between the cooling contact body and the target is provided with a friction-reducing layer.

The invention relates to a sputtering cathode, in particular in accord with the magnetron principle according to claim 1, a method for production according to claim 9, a target according to claim 17 as well as a vacuum coating installation according to claim 22.

Generally known are vacuum coating installations for plasma applications comprising substantially a vacuum receptacle, accepting the substrates to be coated, and one or several sputtering cathodes. These cathodes, in turn, are substantially comprised of a target of the material to be sputtered, a cooling contact body disposed behind it as well as a basic cathode body, comprising a cooling arrangement, for example a cooling circulation, on which the cooling contact body as well as the target are attached. By target is here and in the following understood an integral target (monoblock target) as well as also assembled targets (compound targets), in which the sputtering material proper is bonded onto a back plate, for example by soldering, adhesion, welding on, casting on or another known way.

A sputtering cathode conventionally comprises further a magnet system, which carries out the guidance of the plasma on the target surface as well as further arrangements and (electrical) operating means, which however are not of significance for the further consideration.

During the operation of such sputtering cathodes, specifically of high sputtering power, the target undergoes high heating, such that adequate cooling must be assured. Since simultaneously the target is consumable and must be frequently replaced, a multiplicity of solutions are known from prior art, which are to make feasible both requirements.

It is for example known to dispose the target detachably on a cooling contact body developed as a rigid cooling plate, which body in turn is cooled by a fluid coolant circulation. When the target is replaced, the cooling circulation remains closed. Of disadvantage is here that a large-area contact of target and cooling plate is a precondition for the uniform heat dissipation, which can only with difficulty be realized mechanically.

Alternatively, the use of metal foils or thin sheet metal as the cooling contact body has been proposed, which, on the one hand, close off a hollow volume in the basic cathode body developed as a trough or channel and filled with a cooling medium and, on the other hand, contact the backside of the target. The pressure of the cooling medium presses the metal foil onto the target backside and ensures a uniform heat transfer. For the target replacement the cooling circulation is relieved (retained pressureless).

DE 40 15 388 A1 shows such an arrangement by example. In addition, in this document between target backside and cooling contact body a layer of material of low sputter rate is applied, which is intended to prevent the sputtering-through.

The problem of different coefficients of thermal expansion of the cooling plate/metal foil (for example copper) in opposition to the target (for example aluminum) is unsolved in prior art. This leads to the fact that in operation the two metal faces undergo friction. These cyclical lateral relative movements are most strongly noticeable at the margin of cooling plate/foil and target, while they are minimal in the center of the faces. In particular in the regions of strongest movement, friction welding (cold welding) may occur. In the proximity of these welding sites, as a consequence, cyclic thermal expansions occur leading to irreversible stresses and possibly cracks and tears in the cooling plate/foil. These reduce the cooling efficiency and lead to irreparable damage of the cooling plate/foil. In operation the heat transfer becomes thus locally varying and not reproducible; thereby the quality of the coated substrates can also be negatively affected. Moreover, through the cold-welded connection the target replacement is hindered, during the disassembly damage of the cooling plate may occur which requires repair/replacement, necessitates longer downtimes and consequently reduces the economic efficiency.

The present invention therefore has as its aim to eliminate the disadvantages of prior art. The aim is in particular to increase the service life of the cooling plate/foil of sputtering cathodes in vacuum coating installations and to prevent the cold welding of target and cooling plate/foil and ensure reproducible good heat transfer.

The friction-reducing layer according to the invention must furthermore fulfill a number of further criteria:

The heat efflux from the target to the cooling circulation must only be minimally impaired, especially the surface homogeneity of the heat conduction.

The friction reducing layer must be resistant to abrasion, uniformly thin and hard.

It must be electrically as well as thermally conductive, nonpoisonous, unproblematic in handling and renewable.

Ideally the layer must also not cause any contamination for the operation of the receptacle. Expressed differently, no outgassing and long-term changes of the layer must take place.

At temperatures above 200 degrees as well as at the temperature differences occurring between operation and standstill, it must not develop cracks or spall off.

It must be chemically inert with respect to the operating conditions of the vacuum installation.

It must be cost-effective and simple in production.

The above listed requirements are met according to the invention by a sputtering cathode on whose contact face between cooling contact body and target a friction-reducing layer is applied. It can be comprised, for one, of refractory metals, and by “refractory” in the sense known in technology is understood non-sensitive, heat resistant, fire resistant (Definition see, for example, Römpps Chemie Lexikon, Frankhsche Verlagshandlung). Among them are, but not exclusively, for example, Cr, Mo, Ta, Nb, W or their alloys. As friction-reducing layers are also considered hard material layers, which build on metals of groups 4a to 6a of the periodic table of elements, for example Ti, Zr, Hf of group 4a, V, Nb, Ta of group 5a and Cr, Mo, W of group 6a. The carbides, nitrides and carbonitrides of these metals are employed as friction-reducing layers. As a third group of friction-reducing layers are considered, in addition, the groups of amorphous diamond-like carbon layers (DLC, diamond-like carbon). Depending on the application, these can be pure DLC layers or metal-containing DLC layers.

The thickness of the friction-reducing layer is 0.1 to 5 μm, preferably 0.5 to 2.5 μm.

The dependent claims relate each to particular advantageous further implementations.

One method according to the invention comprises providing the contact face between cooling contact body and target of a sputtering cathode with a friction-reducing layer. These layers can be comprised of refractory metals, preferably of Cr, Mo, Ta, Nb, W or their alloys. Further are considered carbides, nitrides or carbonitrides of the metals of groups 4a to 6a or amorphous diamond-like carbon layers in pure or metal-containing development. Depending on the application feasibility, the coating methods include PVD methods (physical vapor deposition), among them sputtering, in particular magnetron sputtering, as reactive methods with corresponding nitrogen, carbon or oxygen-containing gaseous compounds. Vapor depositions, also reactive ones, are conceivable, as well as cathodic arc methods. Further possible are CVD methods (chemical vapor deposition), also plasma-enhanced methods.

Before the application of the friction-reducing layer, in a further embodiment the backside of the target is subjected to a plasma-enhanced pretreatment step, preferably a plasma cleaning or plasma etching step. Further advantages are thereby attained, in particular with respect to the adhesiveness and durability of the layer.

In a strongly preferred variant according to the invention, the friction-reducing layer is applied on the backside of the target. Moreover, depending on the purpose of application, alternatively or additionally, also the cooling contact body can be provided with such a friction-reducing layer.

The advantage of a target coated according to the invention is that all of the above requirements are met and moreover the compatibility with noncoated target remains ensured, in other words when employed in a coating installation, no changes of the cathode configurations are necessary.

Moreover, from the above can be derived that the application of the invention in cathodes with non-sputtering targets, such as are employed in chemical plasma etching and purification processes, is possible and also offers the described advantages.

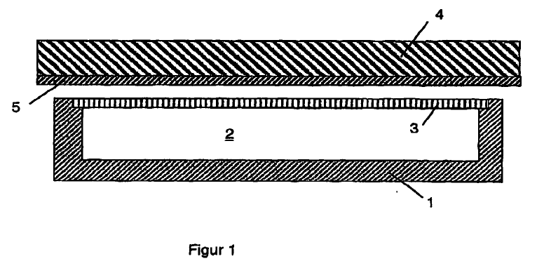

In the following the invention will be explained by example and in conjunction with the schematic FIG. 1. This figure depicts a preferred embodiment variant with coated target.

The basic cathode body 1 is shown schematically in section. It is developed in the form of a trough and comprises a region 2 filled with cooling means, which, during the operation, is circulating in a closed circuit. The trough is closed off by cooling contact body 3 such that it is fluid-tight and vacuum-tight. This body can be developed as a rigid or semirigid plate or metal foil. The target 4 is shown spaced apart from the cooling contact body, which corresponds to the mounted position. On the side facing the cooling contact body a layer 5 according to the invention is applied. Through suitable attachment means (not shown) during operation the target 4 with the layer 5 is detachably connected on the basic cathode body 1 such that the target held in position against the cooling contact body forms an intimate heat-conducting connection with the cooling contact body 3.

1. Sputtering cathode, in particular according to the magnetron principle, substantially comprised of a basic cathode body (1) with cooling arrangement (2), cooling contact body (3) disposed between the cooling arrangement (2) and a target (4) such that it is heat conducting, characterized in that the contact face between cooling contact body (3) and the target (4) is provided with a friction-reducing layer (5).

2. Sputtering cathode as claimed in claim 1, characterized in that the friction-reducing layer (5) is formed of a refractory metal or refractory metal-containing alloy.

3. Sputtering cathode as claimed in claim 1, characterized in that the friction-reducing layer (5) is formed of Cr, Mo, Ta, NB, W or alloys thereof.

4. Sputtering cathode as claimed in claim 1, characterized in that the friction-reducing layer is developed as a hard material layer of carbides, nitrides or carbonitrides of metals of group 4a, 5a or 6a.

5. Sputtering cathode as claimed in claim 1, characterized in that the friction-reducing layer is developed as an amorphous diamond-like carbon layer, in particular as a pure DLC layer or metal-containing DLC layer.

6. Sputtering cathode as claimed in claim 1, characterized in that the thickness of the friction-reducing layer (5) is 0.1 to 5 μm, preferably 0.5 to 2.5 μm.

7. Sputtering cathode as claimed in claim 1, characterized in that the friction-reducing layer (5) is applied on the backside of the target (4).

8. Sputtering cathode as claimed in claim 1, characterized in that the friction-reducing layer (5) is applied on the cooling contact body (3).

9. Method for the production of sputtering cathodes comprised substantially of a basic cathode body (1), a cooling contact body (3) and a target (4), characterized in that the contact face between cooling contact body (3) and target (4) is provided with a friction-reducing layer (5).

10. Method as claimed in claim 9, characterized in that for the friction-reducing layer (5) refractory metal or a refractory metal-containing alloy is utilized.

11. Method as claimed in claim 10, characterized in that for the friction-reducing layer (5) Cr, Mo, Ta, Nb, W or alloys thereof are utilized.

12. Method as claimed in claim 9, characterized in that the layer (5) is applied by means of a PVD method, preferably by magnetron sputtering.

13. Method as claimed in claim 9, characterized in that for the friction-reducing layer carbides, nitrides or carbonitrides of the metals of group 4a, 5a or 6a are employed.

14. Method as claimed in claim 9, characterized in that for the friction-reducing layer amorphous diamond-like carbon layers are selected, in particular pure or metal-containing DLC layers.

15. Method as claimed in claim 13, characterized in that as the coating methods are employed magnetron sputtering, reactive magnetron sputtering, cathodic arc vaporization, vapor deposition, reactive vapor deposition as well as plasma-enhanced CVD.

16. Method as claimed in claim 9, characterized in that before the application of the friction-reducing layer (5) a plasma-enhanced pretreatment step, preferably a plasma etching step, of the target backside is carried out.

17. Target for a sputtering cathode with cooling arrangement (2) and cooling contact body (3), characterized in that the target backside facing the cooling contact body (3) is provided with a friction-reducing layer (5).

18. Target as claimed in claim 17, characterized in that the friction-reducing layer (5) is comprised of refractory metal or a refractory metal-containing alloy.

19. Target as claimed in claim 18, characterized in that the friction-reducing layer (5) is formed of Cr, Mo, Ta, NB, W or alloys thereof.

20. Target as claimed in claim 17, characterized in that the friction-reducing layer is comprised of carbides, nitrides or carbonitrides of the metals of group 4a, 5a or 6a.

21. Target as claimed in claim 17, characterized in that the friction-reducing layer is comprised of amorphous diamond-like carbon layers, in particular pure or metal-containing DLC layers.

22. Vacuum coating installation for plasma applications, comprising substantially a vacuum receptacle to accommodate the substrate, means for evacuating the receptacle as well as one or several sputtering cathode(s) according claim 1.
